(19) United States
(12) Patent Application Publication
(10) Pub. No.: US 2016/0007500 A1
(43) Pub. Date: Jan. 7, 2016

(54) POWER CONVERTER APPARATUS

(71) Applicant: KABUSHIKI KAISHA YASKAWA DENKI, Kitakyushu-shi (JP)

(72) Inventors: Kiyonori KOGUMA, Kitakyushu-shi (JP); Yu UJITA, Kitakyushu-shi (JP); Yoshifumi YAMAGUCHI, Kitakyushu-shi (JP); Tomokazu HONDA, Kitakyushu-shi (JP); Akira SASAKI, Kitakyushu-shi (JP)

(73) Assignee: KABUSHIKI KAISHA YASKAWA DENKI, Kitakyushu-shi (JP)

(21) Appl. No.: 14/854,042

(22) Filed: Sep. 15, 2015

Related U.S. Application Data
(63) Continuation of application No. PCT/JP2013/057709, filed on Mar. 18, 2013.

(51) Int. Cl. H05K 7/20; H02M 7/537

(52) U.S. Cl. CPC H05K 7/2089; H02M 7/537

(57) ABSTRACT

A power converter apparatus is provided, which includes a horizontal switching device, a control switching device connected with the horizontal switching device and for controlling drive of the horizontal switching device, and a heat insulating member disposed between the horizontal switching device and the control switching device and for reducing that heat generated from the horizontal switching device is transferred to the control switching device.

### CROSS-REFERENCE TO RELATED APPLICATION

The present application is a continuation application of International Application No. PCT/JP2013/057709, filed Mar. 18, 2013. The contents of this application are incorporated herein by reference in their entirety.

### TECHNICAL FIELD

This disclosure relates to a power converter apparatus, and particularly to a power converter apparatus provided with a horizontal switching device.

### BACKGROUND

Conventionally, power converter apparatuses provided with a horizontal switching device have been known. Such a power converter apparatus is disclosed in JP2012-222361A, for example.

The power converter apparatus disclosed in JP2012-222361A described above is provided with a III-V group transistor (horizontal switching device) and a IV group vertical-type transistor (control switching device) connected with the III-V group transistor and for controlling the drive of the III-V group transistor. In this power converter apparatus, electrodes of the III-V group transistor are connected with electrodes of the IV group vertical-type transistor so that the electrodes of the III-V group transistor directly contact the electrodes of the IV group vertical-type transistor, respectively.

### SUMMARY

According to one aspect of this disclosure, a power converter apparatus is provided, which includes a horizontal switching device, a control switching device connected with the horizontal switching device and for controlling drive of the horizontal switching device, and a heat insulating member disposed between the horizontal switching device and the control switching device and for reducing that heat generated from the horizontal switching device is transferred to the control switching device.

### BRIEF DESCRIPTION OF THE DRAWINGS

The present disclosure is illustrated by way of example and not by way of limitation in the figures of the accompanying drawings, in which the like reference numerals indicate like elements and in which:

FIG. 1 illustrates a circuit diagram of a three-phase inverter apparatus including a power module according to a first embodiment;

FIG. 2 illustrates a top view of the power module according to the first embodiment;

FIG. 3 illustrates a cross-sectional view taken along a line 200-200 of FIG. 2;

FIG. 4 illustrates a cross-sectional view taken along a line 300-300 of FIG. 2;

FIG. 5 illustrates a cross-sectional view taken along a line 400-400 of FIG. 2;

FIG. 6 illustrates a top view of a first substrate of the power module according to the first embodiment;

FIG. 7 illustrates a bottom view of the first substrate of the power module according to the first embodiment;

FIG. 8 illustrates a bottom, view of the first substrate of the power module according to the first embodiment, where a heat insulating member is placed on the first substrate;

FIG. 9 illustrates a top view of a second substrate of the power module according to the first embodiment;

FIG. 10 illustrates a top view of the second substrate of the power module according to the first embodiment, where components are placed on the second substrate;

FIG. 11 illustrates a plan view of a horizontal switching device according to the first embodiment, seen from a surface side where a drain electrode, a source electrode, and a gate electrode are provided;

FIG. 12 illustrates a cross-sectional view of the first substrate of the power module according to the first embodiment, where a control switching device is mounted on the first substrate;

FIG. 13 illustrates a cross-sectional view of the second substrate of the power module according to the first embodiment, where components are mounted on the second substrate;

FIG. 14 illustrates a cross-sectional view of the second substrate of the power module according to the first embodiment, where the second substrate is filled up with a heat conducting member;

FIG. 15 is a cross-sectional view illustrating a state where the first substrate, the second substrate, and the heat insulating member of the power module according to the first embodiment are joined;

FIG. 16 is a cross-sectional view illustrating a state where the control switching device of the power module according to the first embodiment is wired;

FIG. 17 illustrates a bottom view of a first substrate of a power module according to a second embodiment, where a heat insulating member is placed on the first substrate; and

FIG. 18 illustrates a cross-sectional view taken along a line 500-500 of FIG. 17.

### DETAILED DESCRIPTION

Hereinafter, several embodiments will be described with reference to the accompanying drawings.

### First Embodiment

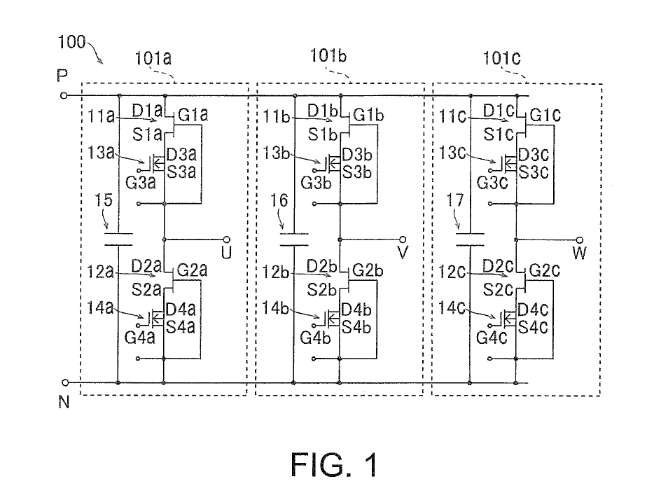

First, referring to FIG. 1, a configuration of a three-phase inverter apparatus 100 according to a first embodiment is described. The three-phase inverter apparatus 100 includes power modules 101a, 101b and 101c. Note that the power modules 101a-101c are examples of “the power converter apparatus,” respectively, and the three-phase inverter apparatus 100 including the power modules 101a-101c is another example of “the power converter apparatus.”

As illustrated in FIG. 1, the three-phase inverter apparatus 100 is constructed by electrically connecting in parallel the three power modules 101a, 101b and 101c for converting power of U-phase, V-phase and W-phase, respectively, and is provided with input terminals P and N, and output terminals U, V and W.

The power modules 101a, 101b and 101c are constructed to convert direct current (DC) power inputted from a DC power source (not illustrated) via the input terminals P and N into alternating current (AC) power of three phases (U-, V- and W-phases), respectively. The power modules 101a, 101b and 101c are configured to output the AC power of U-, V- and W-phases converted as described above to outside via the output terminals U, V and W, respectively. Note that the output terminals U, V and W are connected with an external electrical machinery (not illustrated), such as a motor.

The power module 101a includes two horizontal switching devices 11a and 12a, two control switching devices 13a and 14a connected with the two horizontal switching devices 11a and 12a, respectively, and a snubber capacitor 15. The horizontal switching devices 11a and 12a are both normally-on switching devices. The normally-on switching devices are switching devices that are configured to allow current to flow between drain electrodes D1a and D2a and source electrodes S1a, and S2a when voltages applied to gate electrodes G1a and G2a are 0V, respectively. The control switching devices 13a and 14a are both normally-off switching devices. The normally-off switching devices are switching devices that are configured to prohibit current to flow between a drain electrode D3a and a source electrode S3a, and between a drain electrode D4a and a source electrode S4a, when voltages applied to the gate electrodes G3a and G4a are 0V, respectively. The control switching devices 13a and 14a are connected with the horizontal switching devices 11a and 12a in a cascode fashion, respectively.

The gate electrode G1a (G2a) of the horizontal switching device 11a (12a) is connected with the source electrode S3a (S4a) of the control switching device 13a (14a). Thus, the control switching device 13a (14a) is configured to control the drive (switching) of the horizontal switching device 11a (12a) by switching based on a control signal inputted into the gate electrode G3a (G4a). As the result, the switching circuit comprised of the normally-on horizontal switching device 11a (12a) and the normally-off control switching device 13a (14a) is configured to be controlled as a normally-off switching circuit as a whole.

The power module 101b also includes two normally-on horizontal switching devices 11b and 12b, two normally-off control switching devices 13b and 14b connected with the two horizontal switching devices 11b and 12b in a cascode fashion, respectively, and a snubber capacitor 16, similar to the power module 101a described above. A normally-off switching circuit is comprised of the normally-on horizontal switching device 11b (12b) and the normally-off control switching device 13b (14b). Note that the control switching device 13b (14b) is configured to control the switching of the horizontal switching device 11b (12b) by switching based on a control signal inputted into a gate electrode G3b (G4b).

The power module 101c also includes two normally-on horizontal switching devices 11c and 12c, two normally-off control switching devices 13c and 14c connected with the two horizontal switching devices 11c and 12c in a cascode fashion, respectively, and a snubber capacitor 17, similar to the power modules 101a and 101b described above. A normally-off switching circuit is comprised of the normally-on horizontal switching device 11c (12c) and the normally-off control switching device 13c (14c). Note that the control switching device 13c (14c) is configured to control the switching of the horizontal switching device 11c (12c) by switching based on a control signal inputted into a gate electrode G3c (G4c).

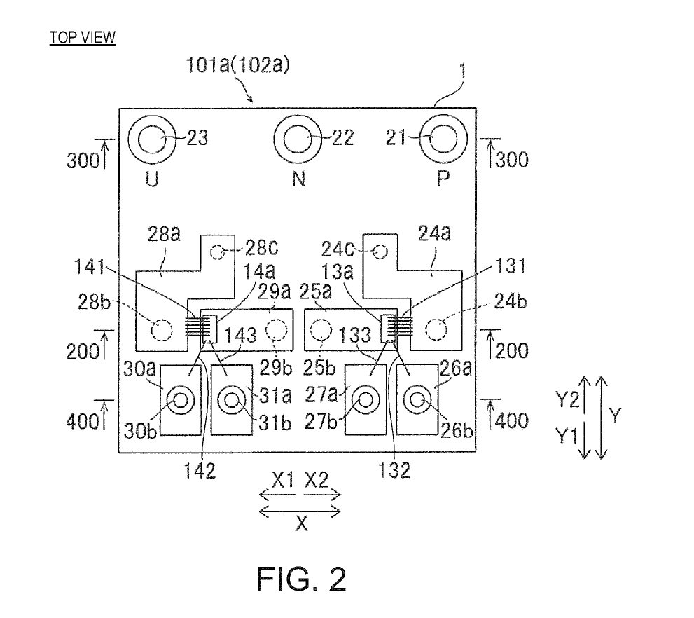

Next, referring to FIGS. 2 to 11, a specific configuration (structure) of the power modules 101a, 101b and 101c according to the first embodiment is described. Note that since the power modules 101a, 101b and 101c have substantially the same configuration, only the power module 101a for converting power of U-phase will be particularly described below.

First, as illustrated in FIGS. 2 to 4, the power module 101a that is one example of the power converter apparatus includes, in one embodiment, a horizontal switching device, a control switching device connected with the horizontal switching device and for controlling drive of the horizontal switching device, and a means for reducing that heat generated from the horizontal switching device is transferred to the control switching device.

In one embodiment, the power module 101a that is one example of the power converter apparatus includes a first substrate 1, a second substrate 2, and two horizontal switching devices 11a and 12a, two control switching devices 13a and 14a, a snubber capacitor 15, two heat insulating members 18a and 18b, two heat conducting members 19a and 19b, and a sealing resin 20. Here, each of the horizontal switching devices 11a and 12a is one example of the horizontal switching device described above, each of the control switching devices 13a and 14a is one example of the control switching device described above, and each of the heat insulating members 18a and 18b is one example of the means “for reducing that heat is transferred to the control switching device.”

Further, the second substrate 2, the horizontal switching device 11a (12a), the heat insulating member 18a (18b), the first substrate 1, and the control switching device 13a (14a) are laminated in this order from the bottom.

The first substrate 1 has a thermal conductivity of about 0.5 to about 1 W/mK, and the second substrate 2 has a thermal conductivity of about 50 W/mK. The heat insulating members 18a and 18b have a thermal conductivity of about 0.1 W/mK, and the heat conducting members 19a and 19b have a thermal conductivity of about 1 to about 5 W/mK. The sealing resin 20 has a thermal conductivity of about 0.1 to about 0.5 W/mK. Note that the values of thermal conductivity are merely reference values when implementing this embodiment, and are not intended to be limited to the values shown in this disclosure.

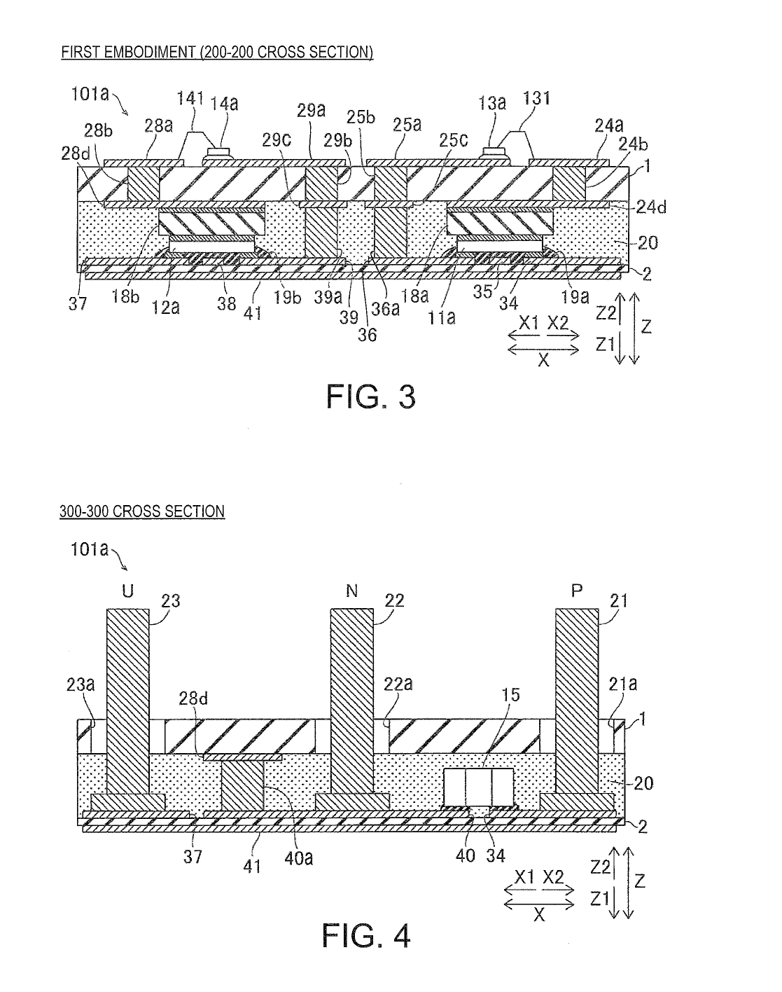

As illustrated in FIG. 3, the first substrate 1 and the second substrate 2 are arranged so as to be vertically (in Z directions) separated from each other by a predetermined distance. Particularly, the first substrate 1 is arranged at an upward location (in a Z2 direction), and the second substrate 2 is arranged at a downward location below the first substrate 1 (in a Z1 direction). The horizontal switching device 11a, the horizontal switching device 12a, and the snubber capacitor 15 (refer to FIG. 4) are disposed between a lower surface (the surface in the Z1 direction) of the first substrate 1, and an upper surface (the surface in the Z2 direction) of the second substrate 2. The control switching device 13a and the control switching device 14a are disposed on the upper surface of the first substrate 1. The sealing resin 20 is filled up between the lower surface of the first substrate 1 and the upper surface of the second substrate 2.

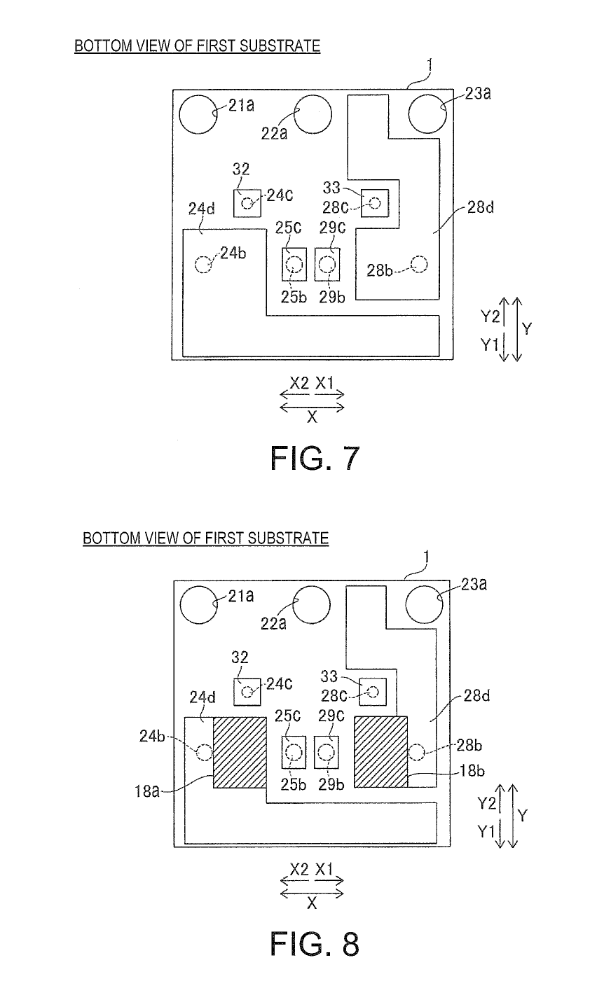

As illustrated in FIGS. 4 and 6, through holes 21a, 22a and 23a are formed in the first substrate 1 so as to penetrate the first substrate 1 in the vertical directions (in the Z directions). As illustrated in FIG. 6, on the upper surface (in the Z2 direction) of the first substrate 1, conductive patterns 24a, 25a, 26a, 27a, 28a, 29a, 30a and 31a are formed. In the meantime, as illustrated in FIG. 7, conductive patterns 24d, 25c, 28d, 29c, 32 and 33 are formed on the lower surface (in the Z1 direction) of the first substrate 1.

As illustrated in FIGS. 6 and 7, the conductive patterns 24a and 24d are connected with each other by an electrode 24b penetrating through the first substrate 1. The conductive patterns 24a and 32 are connected with each other by an electrode 24c penetrating through the first substrate 1. The conductive patterns 25a and 25c are connected with each other by an electrode 25b penetrating through the first substrate 1. The conductive patterns 28a and 28d are connected with each other by an electrode 28b penetrating through the first substrate 1. The conductive patterns 28a and 33 are connected with each other by an electrode 28e penetrating through the first substrate 1. The conductive patterns 29a and 29c are connected with each other by an electrode 29b penetrating through the first substrate 1. Note that each of the electrodes 24b and 28b is one example of “the penetrating electrode.”

As illustrated in FIG. 3, the penetrating electrode 24b (28b) is constructed so as to connect the heat insulating member 18a (18b) with the control switching device 13a (14a). As illustrated in FIGS. 2 and 3, the electrode 24b (28b) is disposed at a position offset from the control switching device 13a (14a) in a plan view (seen in the Z directions).

As described above, the first substrate 1 is made of a material having a thermal conductivity of about 0.5 to about 1 W/mK. That is, the first substrate 1 is lower in the thermal conductivity than the heat conducting member 19a (19b) that has a thermal conductivity of about 1 to about 5 W/mK.

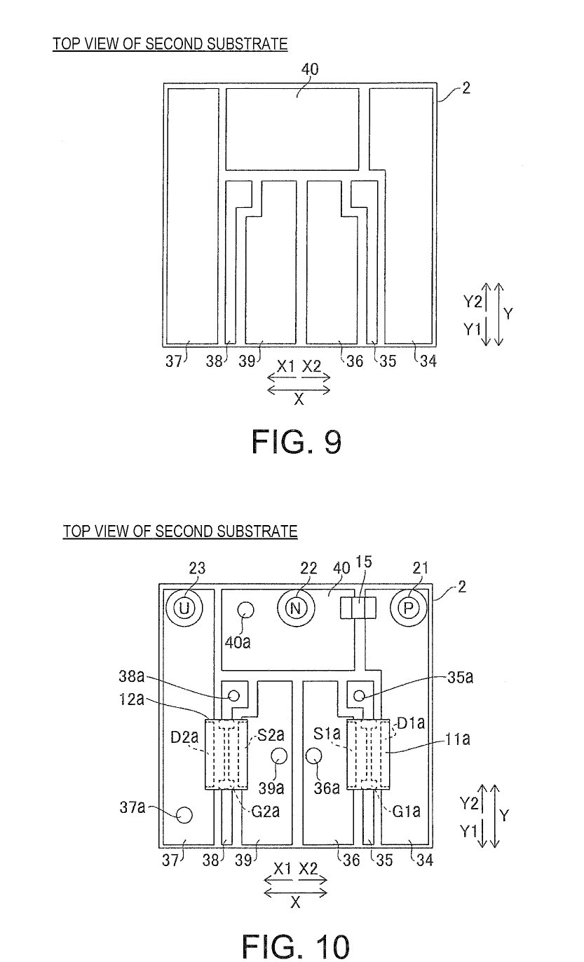

As illustrated in FIG. 9, on the upper surface (in the Z2 direction) of the second substrate 2, conductive patterns 34, 35, 36, 37, 38, 39 and 40 are formed. As illustrated in FIGS. 3 to 5, a conductive pattern 41 is formed on the lower surface (in the Z1 direction) of the second substrate 2. As described above, the second substrate 2 is made of a material having a thermal conductivity of about 50 W/mK. That is, the second substrate 2 is higher in the thermal conductivity than both the heat conducting member 19a (19b) that has the thermal conductivity of about 1 to about 5 W/mK and the heat insulating member 18a (18b) that has the thermal conductivity of about 0.1 W/mK.

As illustrated in FIGS. 2 and 4, pillar-shaped conductors 21, 22 and 23 are disposed via the through holes 21a, 22a and 23a of the first substrate 1, respectively. The pillar-shaped conductor 21 is connected at one end thereof with the input terminal P, and at the other end with the conductive pattern 34 of the second substrate 2. The pillar-shaped conductor 22 is connected at one end thereof with the input terminal N, and at the other end with the conductive pattern 40 of the second substrate 2. The pillar-shaped conductor 23 is connected at one end thereof with the output terminal U, and at the other end with the conductive pattern 37 of the second substrate 2.

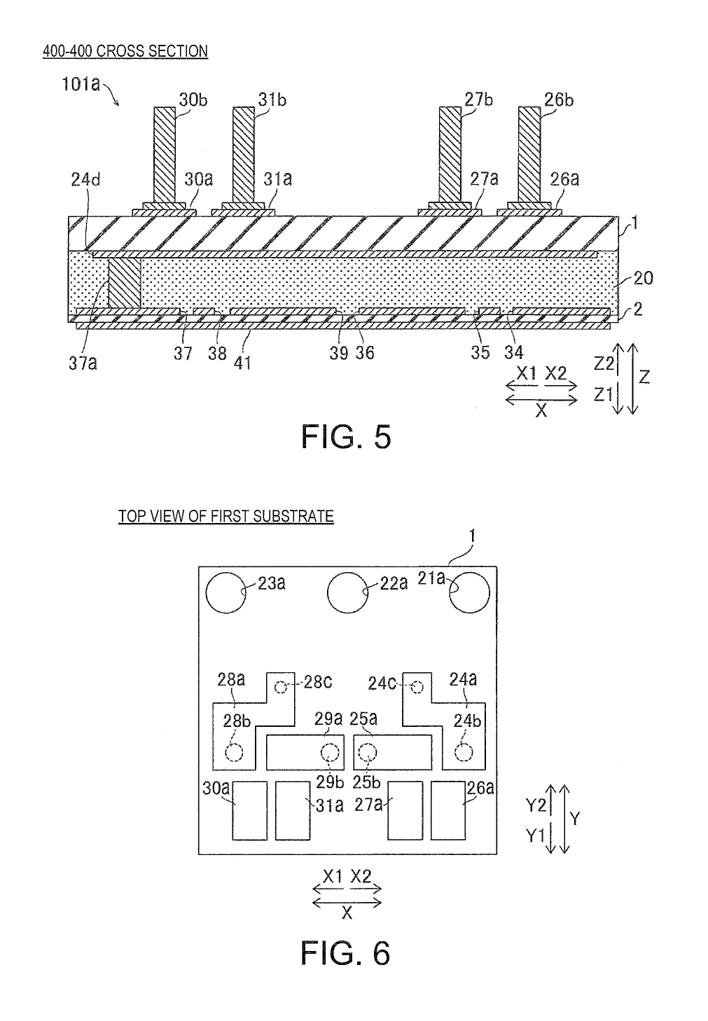

As illustrated in FIG. 5, a pillar-shaped electrode 26b is connected with the conductive pattern 26a on the upper surface (in the Z2 direction) of the first substrate 1. The pillar-shaped electrode 26b is also connected with an external electrode (not illustrated). A pillar-shaped electrode 27b is connected with the conductive pattern 27a. The pillar-shaped electrode 27b is also connected with a circuit (not illustrated) which generates a control signal for controlling the gate electrode G3a of the control switching device 13a. A pillar-shaped electrode 30b is connected with the conductive pattern 30a. The pillar-shaped electrode 30b is also connected with an external electrode (not illustrated). A pillar-shaped electrode 31b is connected with the conductive pattern 31a. The pillar-shaped electrode 31b is also connected with a circuit (not illustrated) which generates a control signal for controlling the gate electrode G4a of the control switching device 14a.

As illustrated in FIGS. 3, 7, and 10, the conductive pattern 25c of the first substrate 1 is connected with the conductive pattern 36 of the second substrate 2 by a pillar-shaped electrode 36a. The conductive pattern 29c of the first substrate 1 is connected with the conductive pattern 39 of the second substrate 2 by a pillar-shaped electrode 39a.

As illustrated in FIGS. 7 and 10, the conductive pattern 24d of the first substrate 1 is connected with the conductive pattern 35 of the second substrate 2 by a pillar-shaped electrode 35a. The conductive pattern 28d of the first substrate 1 is also connected with the conductive pattern 38 of the second substrate 2 by a pillar-shaped electrode 38a.

As illustrated in FIGS. 5, 7 and 10, the conductive pattern 24d of the first substrate 1 is also connected with the conductive pattern 37 of the second substrate 2 by a pillar-shaped electrode 37a. As illustrated in FIGS. 4, 7 and 10, the conductive pattern 28d of the first substrate 1 is connected with the conductive pattern 40 of the second substrate 2 by a pillar-shaped electrode 40a.

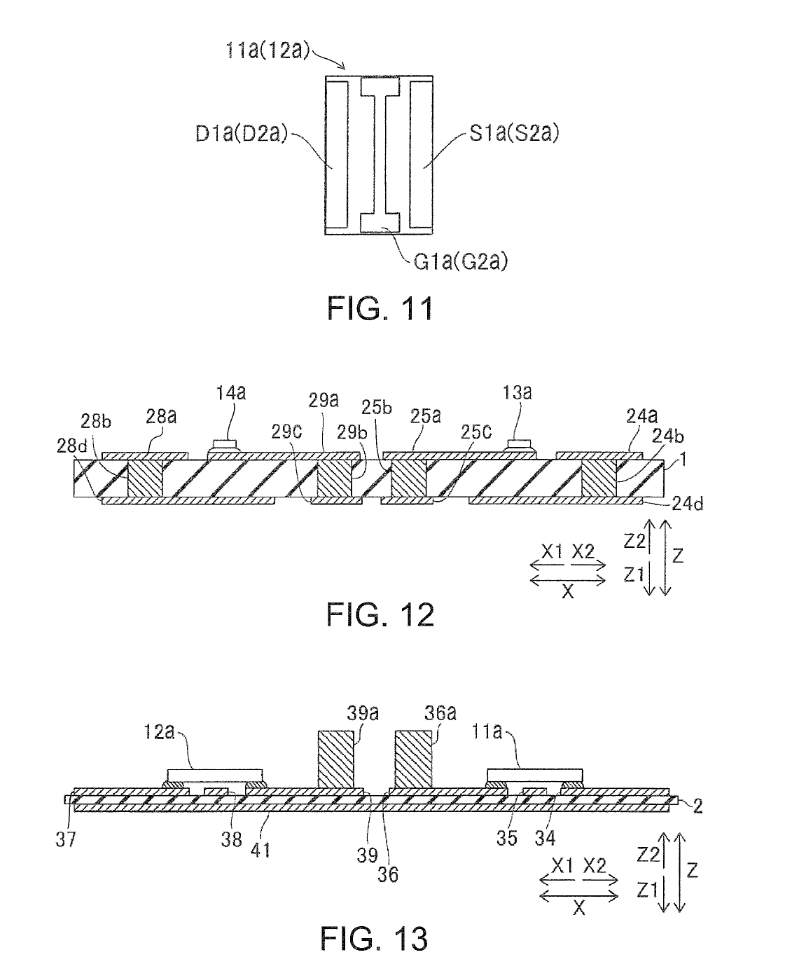

As illustrated in FIG. 11, the horizontal switching device 11a (12a) is constructed so that the gate electrode G1a (G2a), the source electrode S1a (S2a), and the drain electrode D1a (D2a) are provided on the same surface. That is, the horizontal switching device 11a (12a) mainly generates heat from the surface where the electrodes are provided because current mainly flows through one of the surfaces where the electrodes are provided when the horizontal switching device 11a (12a) is driven. In other words, the surface of the horizontal switching device 11a (12a) where the electrodes are provided becomes a heat-generating surface. The horizontal switching device 11a (12a) is made of a semiconducting material containing gallium nitride (GaN). The horizontal switching device 11a (12a) of this embodiment has a heat resistance against a temperature of about 200° C.

As illustrated in FIGS. 3 and 10, in the horizontal switching device 11a (12a), the drain electrode D1a (D2a) is connected with the conductive pattern 34 (37) of the second substrate 2. In the horizontal switching device 11a (12a), the source electrode S1a (S2a) is connected with the conductive pattern 36 (39) of the second substrate 2. In the horizontal switching device 11a (12a), the gate electrode G1a (G2a) is connected with the conductive pattern 35 (38) of the second substrate 2.

As illustrated in FIG. 3, in the horizontal switching device 11a (12a), the gate electrode G1a (G2a), the source electrode S1a (S2a), and the drain electrode D1a (D2a) which are provided downwardly (in the Z1 direction) are joined to the respective conductive patterns of the lower second substrate 2 via a joining layer made of solder, etc. That is, the horizontal switching device 11a (12a) is joined to the second substrate 2 so that the heat-generating surface of the horizontal switching device 11a (12a) is oriented toward the second substrate 2.

The control switching device 13a (14a) is comprised of a vertical device having the gate electrode G3a (G4a), the source electrode S3a (S4a), and the drain electrode D3a (D4a). Specifically, as for the control switching device 13a (14a), the gate electrode G3a (G4a) and the source electrode S3a (S4a) are oriented upwardly (in the Z2 direction), and the drain electrode D3a (D4a) is oriented downwardly (in the Z1 direction). The control switching device 13a (14a) is made of a semiconducting material containing silicon (Si). The control switching device 13a (14a) of this embodiment has a heat resistance against a temperature of about 150° C.

The control switching device 13a (14a) is disposed on the upper surface (in the Z2 direction) of the first substrate 1. Specifically, as for the control switching device 13a (14a), as illustrated in FIGS. 2 and 3, the drain electrode D3a (D4a) is connected with the conductive pattern 25a (29a) of the first substrate 1 via a joining layer made of solder, etc. As for the control switching device 13a (14a), the source electrode S3a (S4a) is connected with the conductive patterns 24a and 26a (28a and 30a) of the first substrate 1 via wires 131 and 132 (141 and 142) made of metal, such as aluminum or copper, respectively. As for the control switching device 13a (14a), the gate electrode G3a (G4a) is connected with the conductive pattern 27a (31a) of the first substrate 1 via wire 133 (143) made of metal, such as aluminum or copper. The control switching device 13a (14a) is disposed via the heat insulating member 18a (18b) on the opposite side (in the Z2 direction) from the heat-generating surface of the horizontal switching device 11a (12a).

As illustrated in FIG. 10, the snubber capacitor 15 is disposed so as to connect the conductive pattern 40 of the second substrate 2 with the conductive pattern 34 of the second substrate 2.

Here, in the first embodiment, as illustrated in FIG. 3, the heat insulating member 18a (18b) is disposed between the horizontal switching device 11a (12a) and the control switching device 13a (14a) so as to reduce that the heat generated from the horizontal switching device 11a (12a) is transferred to the control switching device 13a (14a). Specifically, the heat insulating member 18a (18b) is disposed above (in the Z2 direction) the horizontal switching device 11a (12a) so that the heat insulating member 18a (18b) entirely covers the surface opposite (in the Z2 direction) from the heat-generating surface of the horizontal switching device 11a (12a). The heat insulating member 18a (18b) includes an insulation member (e.g., nano-porous silica) and a metallized layer formed on the surface of the insulation member.

The metallized layer of the heat insulating member 18a (18b) is electrically connected with the source electrode S3a (S4a) of the control switching device 13a (14a). Specifically, as illustrated in FIG. 8, the upper surface (in the Z2 direction) of the metallized layer of the heat insulating member 18a (18b) is connected with the conductive pattern 24d (28d) of the first substrate 1 via a joining layer made of solder, etc. The lower surface (in the Z1 direction) of the metallized layer of the heat insulating member 18a (18b) is connected with the surface opposite (in the Z2 direction) from the surface where the electrodes of the horizontal switching device 11a (12a) are disposed via a joining layer made of solder, etc.

In the first embodiment, the heat conducting member 19a (19b) having a higher thermal conductivity than the heat insulating member 18a (18b) is disposed on the opposite side (in the Z1 direction) from the control switching device 13a (14a) with respect to the horizontal switching device 11a (12a). The heat conducting member 19a (19b) is made of an insulating material. Specifically, the heat conducting member 19a (19b) is made of resin, such as polyimide, where fillers made of ceramic (e.g., boron nitride (BN)) are distributed.

The heat conducting member 19a (19b) is disposed on the heat-generating surface side (in the Z1 direction) of the horizontal switching device 11a (12a). That is, the heat conducting member 19a (19b) is filled up between the horizontal switching device 11a (12a) and the second substrate 2. Thus, it is configured that the heat generated from the heat-generating surface (the surface in the Z1 direction) of the horizontal switching device 11a (12a) is transmitted toward the second substrate 2 (in the Z1 direction) via the heat conducting member 19a (19b).

The sealing resin 20 is filled up between the lower surface (the surface in the Z1 direction) of the first substrate 1 and the upper surface (the surface in the Z2 direction) of the second substrate 2. That is, the horizontal switching device 11a (12a), the heat insulating member 18a (18b), and the heat conducting member 19a (19b) are sealed with the sealing resin 20. The sealing resin 20 has a thermal conductivity lower than the heat conducting member 19a (19b). The sealing resin 20 has a high heat resistance. The sealing resin 20 is made of epoxy resin, for example.

Next, referring to FIGS. 3 and 12 to 16, a method of assembling the power module 101a according to the first embodiment is described.

The method of assembling the power module 101a includes mounting the control switching device 13a (14a) on the first substrate 1, mounting components on the second substrate 2, filling up the second substrate 2 with the heat conducting member 19a (19b), joining the first substrate 1, the second substrate 2, and the heat insulating member 18a (18b), wiring the control switching device 13a (14a), and sealing with the sealing resin 20.

Upon mounting the control switching device 13a (14a) on the first substrate 1, as illustrated in FIG. 12, the control switching device 13a (14a) is disposed on the surface of the first substrate 1, on the opposite side (in the Z2 direction) from the horizontal switching device 11a (12a). Specifically, the drain electrode D3a (D4a) of the control switching device 13a (14a) is connected with the conductive pattern 25a (29a) of the first substrate 1 via a joining layer made of solder, etc.

Upon mounting the components on the second substrate 2, as illustrated in FIGS. 10 and 13, the horizontal switching devices 11a and 12a, the snubber capacitor 15, the pillar-shaped conductors 21, 22 and 23, and the pillar-shaped electrodes 35a, 36a, 37a, 38a, 39a and 40a are mounted (disposed) on the upper surface (in the Z2 direction) of the second substrate 2.

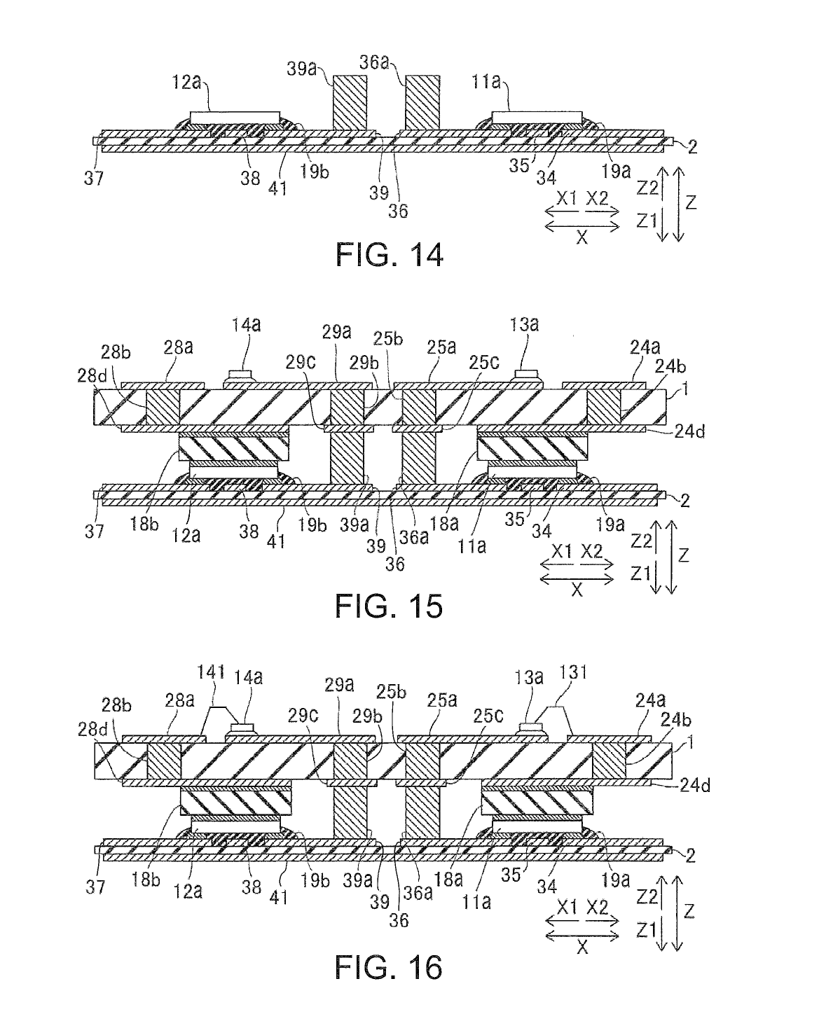

Upon filling up the second substrate 2 with the heat conducting member 19a (19b), as illustrated in FIG. 14, the heat conducting member 19a (19b) is filled up between the horizontal switching device 11a (12a) and the second substrate 2.

Upon joining the first substrate 1, the second substrate 2, and the heat insulating member 18a (18b), as illustrated in FIG. 15, the second substrate 2, the heat insulating member 18a (18b), and the first substrate 1 are laminated in this order from the bottom, and they are mutually joined via the joining layers.

Upon wiring the control switching device 13a (14a), as illustrated in FIGS. 2 and 16, the source electrode S3a (S4a) of the control switching device 13a (14a) is connected with the conductive patterns 24a and 26a (28a and 30a) of the first substrate 1 via the wires 131 and 132 (141 and 142) made of metal, such as aluminum or copper, respectively. The gate electrode G3a (G4a) of the control switching device 13a (14a) is connected with the conductive pattern 27a (31a) of the first substrate 1 via the wire 133 (143) comprised of metal, such as aluminum or copper.

Upon sealing with the sealing resin 20, as illustrated in FIG. 3, the sealing resin 20 is filled up between the lower surface (the surface in the Z1 direction) of the first substrate 1 and the upper surface (the surface in the Z2 direction) of the second substrate 2, thereby sealing therebetween. The power module 101a is thus assembled as described above. Note that the method of assembling the power module 101a is described above; however, the power modules 101b and 101c can similarly be assembled. Alternatively, the power modules 101a-101c may be integrally assembled using common first and second substrates.

In the first embodiment, as described above, the heat insulating member 18a (18b) is provided, that is disposed between the horizontal switching device 11a (12a) and the control switching device 13a (14a), and reduces that the heat generated from the horizontal switching device 11a (12a) is transferred to the control switching device 13a (14a). Thus, the heat insulating member 18a (18b) reduces that the heat generated from the horizontal switching device 11a (12a) is transferred to the control switching device 13a (14a). Therefore, the heat insulating member 18a (18b) controls a deterioration of electrical properties of the control switching device 13a (14a). As the result, the heat insulating member 18a (18b) can control a deterioration of power converting function of the power module 101a (three-phase inverter apparatus 100).

In the first embodiment, as described above, the heat conducting member 19a (19b) is provided, that is disposed on the opposite side (in the Z1 direction) of the horizontal switching device 11a (12a) from the control switching device 13a (14a), and has a higher thermal conductivity than the heat insulating member 18a (18b). Thus, the heat generated from the horizontal switching device 11a (12a) is suitably transmitted to the opposite side from the control switching device 13a (14a) via the heat conducting member 19a (19b). Therefore, the heat conducting member 19a (19b) can effectively control the heat being transferred to the control switching device 13a (14a).

In the first embodiment, as described above, the heat conducting member 19a (19b) is made of the insulating material. Thus, a short-circuit of the electrodes of the horizontal switching device 11a (12a) can be prevented, while the heat generated from the horizontal switching device 11a (12a) is transmitted to the opposite direction from the control switching device 13a (14a).

In the first embodiment, as described above, the heat conducting member 19a (19b) is disposed on the heat-generating surface side (in the Z1 direction) of the horizontal switching device 11a (12a). Thus, the heat generated from the horizontal switching device 11a (12a) can efficiently be transmitted by the heat conducting member 19a (19b).

In the first embodiment, as described above, the control switching device 13a (14a) is disposed on the opposite side (in the Z2 direction) from the heat-generating surface of the horizontal switching device 11a (12a) via the heat insulating member 18a (18b). Thus, it can reduce more effectively that the heat generated from the heat-generating surface of the horizontal switching device 11a (12a) is transferred to the control switching device 13a (14a).

In the first embodiment, as described above, the heat insulating member 18a (18b) is disposed so as to cover the entire surface of the horizontal switching device 11a (12a) on the opposite side (in the Z2 direction) from the heat-generating surface thereof. Thus, it can reduce still more effectively that the heat generated from the heat-generating surface of the horizontal switching device 11a (12a) is transferred to the control switching device 13a (14a).

In the first embodiment, as described above, the horizontal switching device 11a (12a) is sealed with the sealing resin 20 having the lower thermal conductivity than the heat conducting member 19a (19b). Thus, it can reduce that the heat generated from the horizontal switching device 11a (12a) is transferred to the control switching device 13a (14a), while reducing foreign matters entering into the horizontal switching device 11a (12a).

In the first embodiment, as described above, the first substrate 1 that is used as wiring is provided between the heat insulating member 18a (18b) and the control switching device 13a (14a). Thus, the heat being transferred to the control switching device 13a (14a) can be reduced also by the first substrate 1.

In the first embodiment, as described above, the first substrate 1 is made of the material having a lower thermal conductivity than the heat conducting member 19a (19b). Thus, the heat being transferred to the control switching device 13a (14a) can effectively be controlled by both the heat insulating member 18a (18b) and the first substrate 1.

In the first embodiment, as described above, the control switching device 13a (14a) is disposed on the surface of the first substrate 1, on the opposite side (in the Z2 direction) from the horizontal switching device 11a (12a). Thus, it can reduce that the heat generated from the horizontal switching device 11a (12a) is transferred to the control switching device 13a (14a), and the control switching device 13a (14a) can easily be disposed on the first substrate 1.

In the first embodiment, as described above, the electrode 24b (28b) made of the conductive material is provided to the first substrate 1 so as to penetrate the first substrate 1, that connects the heat insulating member 18a (18b) with the control switching device 13a (14a). The electrode 24b (28b) is disposed at the position offset from the control switching device 13a (14a) in the plan view (seen in the Z direction). Thus, it can reduce that the heat generated from the horizontal switching device 11a (12a) is transmitted to the control switching device 13a (14a) via the electrode 24b (28b).

In the first embodiment, as described above, the metallized layer of the heat insulating member 18a (18b) is electrically connected with the control switching device 13a (14a). Thus, the metallized layer of the heat insulating member 18a (18b) is connected with the surface opposite (in the Z2 direction) from the electrodes of the horizontal switching device 11a (12a) to fix and stabilize the electric potential of the surface opposite (in the Z2 direction) from the electrodes of the horizontal switching device 11a (12a).

In the first embodiment, as described above, the second substrate 2 is provided, that is disposed on the opposite side (in the Z1 direction) from the horizontal switching device 11a (12a) with respect to the heat conducting member 19a (19b), and where the horizontal switching device 11a (12a) is disposed. Thus, it can reduce that the heat generated from the horizontal switching device 11a (12a) is transferred to the control switching device 13a (14a) side, and the horizontal switching device 11a (12a) can easily be disposed on the second substrate 2.

In the first embodiment, as described above, the heat conducting member 19a (19b) is filled up between the horizontal switching device 11a (12a) and the second substrate 2. Thus, the heat generated from the horizontal switching device 11a (12a) is suitably transmitted to the second substrate 2 via the heat conducting member 19a (19b). Therefore, it can easily reduce that the heat is transferred to the control switching device 13a (14a) side.

In the first embodiment, as described above, the second substrate 2 is made of the material having a higher thermal conductivity than both the heat conducting member 19a (19b) and the heat insulating member 18a (18b). Thus, the heat generated from the horizontal switching device 11a (12a) can easily be radiated from the second substrate 2 side that is opposite from the control switching device 13a (14a).

In the first embodiment, as described above, the second substrate 2, the horizontal switching device 11a (12a), the heat insulating member 18a (18b), the first substrate 1, and the control switching device 13a (14a) are laminated in this order. Thus, the power module 101a (three-phase inverter apparatus 100) which can control a deterioration of the power converting function can easily be assembled.

In the first embodiment, as described above, the control switching device 13a (14a) is connected with the horizontal switching device 11a (12a) in the cascode fashion. Thus, the switching of the horizontal switching device 11b (12b) can easily be controlled by switching based on the control signal inputted into the gate electrode G3a (G4a) of the control switching device 13a (14a).

In the first embodiment, as described above, the control switching device 13a (14a) includes the vertical device. Thus, it can control a deterioration of the power converting function of the power module 101a (three-phase inverter apparatus 100) using the control switching device 13a (14a) of the vertical device.

### Second Embodiment

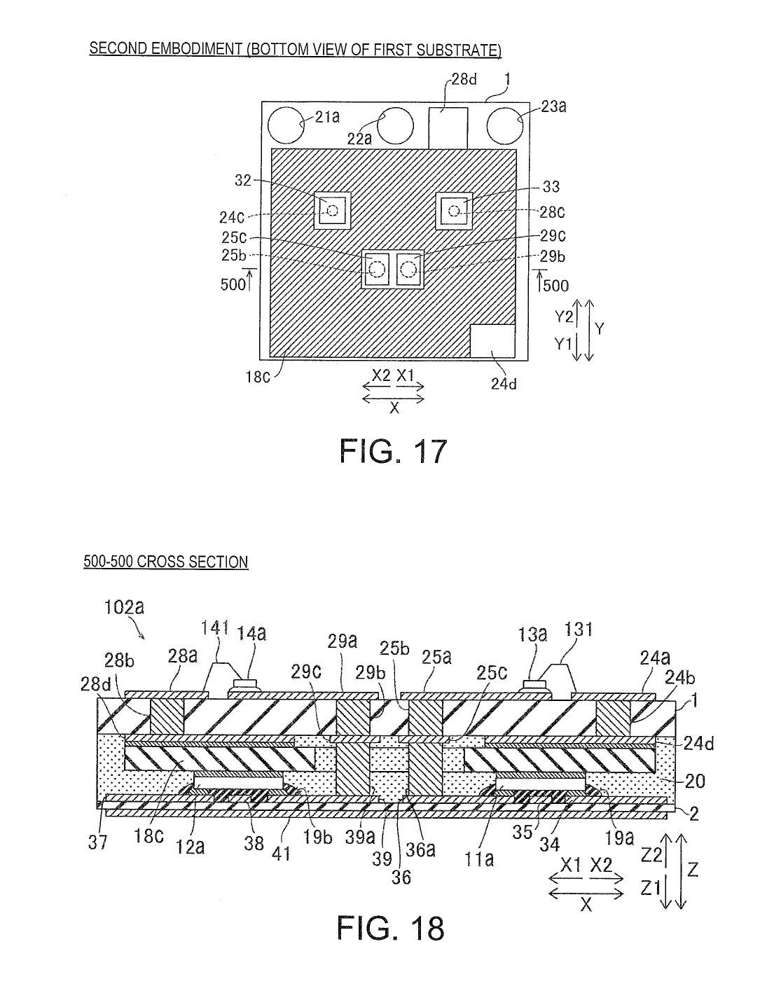

Next, referring to FIGS. 17 and 18, a power module 102a according to a second embodiment is described. The first embodiment described above is configured to cover the horizontal switching devices 11a and 12a by the heat insulating members 18a and 18b, respectively. Unlike the first embodiment, the second embodiment is configured to cover the horizontal switching devices 11a and 12a by a common heat insulating member 18c. Note that the power module 102a is one example of “the power converter apparatus.”

The configuration of the power module 102a according to the second embodiment is described. Note that the power module 102a converts power of U-phase in the three-phase inverter apparatus. That is, also in this second embodiment, two other power modules (power modules that convert power of V- and W-phases) having substantially the same configuration as the power module 102a are separately provided in addition to the power module 102a similar to the first embodiment described above. Below, only the power module 102a that converts the power of U-phase is described for simplifying the explanation.

Here, in the second embodiment, as illustrated in FIG. 17, one heat insulating member 18c is disposed so as to cover the lower surface (in the Z1 direction) of the first substrate 1. Cutouts or through-holes (windows) are formed in the heat insulating member 18c so as to expose the conductive patterns 24d, 25c, 28d, 29c, 32, and 33 of the first substrate 1. As illustrated in FIG. 18, the single heat insulating member 18c is disposed so as to cover both the horizontal switching devices 11a and 12a.

The heat insulating member 18c is disposed between the horizontal switching devices 11a and 12a and the control switching devices 13a and 14a, thereby reducing that heat generated from the horizontal switching device 11a (12a) is transferred to the control switching device 13a (14a). Specifically, as illustrated in FIG. 18, the heat insulating member 18c is disposed above (in the Z2 direction) the horizontal switching devices 11a and 12a so as to cover the entire surfaces opposite (in the Z2 direction) from the heat-generating surfaces of the horizontal switching devices 11a and 12a. The heat insulating member 18c has a thermal conductivity of about 0.1 W/mK.

Note that other configurations of the second embodiment are the same as those of the first embodiment described above.

In the second embodiment, as described above, one heat insulating member 18c is disposed so as to cover the entire surfaces opposite (in the Z2 direction) from the heat-generating surfaces of the two horizontal switching devices 11a and 12a. Thus, propagation of the heat can be reduced over a wide area, while reducing the number of components.

Note that other effects of the second embodiment are the same as those of the first embodiment described above.

Note that the embodiments disclosed herein should be considered to be illustrative in all aspects and should not be considered to be restrictive. The scope of the present disclosure is illustrated by the appended claims but not by the embodiments described above, and encompasses all the changes within the meanings and spirits corresponding to equivalents of the claims.

For example, in the first and second embodiments described above, the three-phase inverter apparatus is illustrated as one example of the power converter apparatus; however, any power converter apparatuses other than the three-phase inverter apparatus may also be applicable.

Further, in the first and second embodiments described above, one example in which the normally-on horizontal switching devices are used is illustrated; however, normally-off horizontal switching devices may also be used.

Further, in the first and second embodiments described above, one example in which the horizontal switching device is made of the semiconducting material containing gallium nitride (GaN) is illustrated; however, the horizontal switching device may also be made of a material of III-V group other than GaN, or a material of IV group, such as diamond (C).

Further, in the first and second embodiments described above, one example in which the heat insulating member is disposed so as to cover the entire surface(s) opposite from the heat-generating surface(s) of the horizontal switching device(s) is illustrated; however, the heat insulating member may be disposed so as to cover part of the horizontal switching device(s).

Further, in the first and second embodiments described above, one example in which the heat insulating member includes the insulation member and the metallized layer is illustrated; however, the heat insulating member may have a configuration other than being comprised of the insulation member and the metallized layer, as long as the heat insulating member can reduce that the heat generated from the horizontal switching device is transferred to the control switching device.

What is claimed is:

1. A power converter apparatus, comprising:
a horizontal switching device;
a control switching device connected with the horizontal switching device and for controlling drive of the horizontal switching device; and
a heat insulating member disposed between the horizontal switching device and the control switching device and for reducing that heat generated from the horizontal switching device is transferred to the control switching device.

2. The power converter apparatus of claim 1, further comprising a heat conducting member disposed opposite from the control switching device with respect to the horizontal switching device, and having a higher thermal conductivity than a thermal conductivity of the heat insulating member.

3. The power converter apparatus of claim 2, wherein the heat conducting member is made of an insulating material.

4. The power converter apparatus of claim 2, wherein the horizontal switching device includes a heat-generating surface, and
wherein the heat conducting member is disposed on the heat-generating surface side of the horizontal switching device.

5. The power converter apparatus of claim 4, wherein the control switching device is disposed via the heat insulating member, on the opposite side from the heat-generating surface of the horizontal switching device.

6. The power converter apparatus of claim 4, wherein the heat insulating member is disposed so as to entirely cover a surface of the horizontal switching device opposite from the heat-generating surface.

7. The power converter apparatus of claim 2, wherein the horizontal switching device is sealed by a sealing resin having a lower thermal conductivity than the thermal conductivity of the heat conducting member.

8. The power converter apparatus of claim 1, further comprising a first substrate disposed between the heat insulating member and the control switching device.

9. The power converter apparatus of claim 8, wherein the first substrate is made of a material having a lower thermal conductivity than a thermal conductivity of the heat conducting member.

10. The power converter apparatus of claim 8, wherein the control switching device is disposed on a surface of the first substrate, opposite from the horizontal switching device.

11. The power converter apparatus of claim 8, wherein the first substrate includes a penetrating electrode provided so as to penetrate the first substrate and made of a conductive material for connecting the heat insulating member with the control switching device, and
wherein the penetrating electrode is disposed at a position offset from the control switching device in a plan view.

12. The power converter apparatus of claim 1, wherein the heat insulating member includes an insulation member and a metallized layer formed on a surface of the insulation member, and
wherein the metallized layer of the heat insulating member is electrically connected with the control switching device.

13. The power converter apparatus of claim 2, further comprising a second substrate disposed on the opposite side from the horizontal switching device with respect to the heat conducting member, the horizontal switching device being disposed on the second substrate.

14. The power converter apparatus of claim 13, wherein the heat conducting member is filled up between the horizontal switching device and the second substrate.

15. The power converter apparatus of claim 13, wherein the second substrate is made of a material having a higher thermal conductivity than the thermal conductivities of the heat conducting member and the heat insulating member.

16. The power converter apparatus of claim 13, wherein the second substrate, the horizontal switching device, the heat insulating member, and the control switching device are laminated in this order.

17. The power converter apparatus of claim 16, further comprising a first substrate on which the control switching device is disposed,
wherein the second substrate, the horizontal switching device, the heat insulating member, the first substrate, and the control switching device are laminated in this order.

18. The power converter apparatus of claim 1, wherein the control switching device is connected with the horizontal switching device in a cascode fashion.

19. The power converter apparatus of claim 1, wherein the control switching device includes a vertical device.

20. A power converter apparatus, comprising:
a horizontal switching device;
a control switching device connected with the horizontal switching device and for controlling drive of the horizontal switching device; and
a means for reducing that heat generated from the horizontal switching device is transferred to the control switching device.
